(19) United States
(12) Patent Application Publication
(10) Pub. No.: US 2002/0153954 A1
(43) Pub. Date: Oct. 24, 2002

(54) Common-mode feedback circuit

(76) Inventor: James R. Hochschild, Plano, TX (US)

Correspondence Address: TEXAS INSTRUMENTS INCORPORATED, P O BOX 655474, M/S 3999, DALLAS, TX, 75265

(21) Appl. No.: 10/122,835

(22) Filed: Apr. 15, 2002

Related U.S. Application Data
(60) Provisional application No. 60/286,302, filed on Apr. 24, 2001.

(51) Int. Cl. H03F 3/45

(52) U.S. Cl. 330/258

(57) ABSTRACT

The opamp has a common mode current injection circuit that monitors the amount of tail current “requested” by the primary common-mode feedback circuit. If this current exceeds the nominal tail current by a certain amount, additional common-mode current is injected into the first stage of the opamp, bypassing the tail source and the input differential pair, to prevent the outputs from latching. This circuit is useful for an opamp in which the common mode feedback (CMFB) loop controls the tail current. When the “requested” tail current exceeds a threshold, additional current is pumped into the first stage to stabilize the CMFB loop.

### FIELD OF THE INVENTION

This invention generally relates to electronic systems and in particular it relates to an improved common mode feedback circuit.

### BACKGROUND OF THE INVENTION

In some differential 2-stage opamps, the common-mode feedback loop can become unstable when the tail source is crushed, causing the outputs to latch to the rail.

A positive common-mode feedback path exists in many differential opamps with an even number of stages through the feedback network around the opamp. The gain of this positive feedback path depends on the external feedback circuit, the gain of the opamp, and the output conductance of the first stage tail current source. To be stable, the negative feedback provided by the common-mode feedback amplifier must exceed this positive feedback. Consider a case where the tail source is connected to the positive rail. If the common-mode input to the amplifier is too high, the tail source will be crushed and its output conductance will rise, increasing the gain of the positive common-mode feedback path. At some point the net common-mode feedback will be positive, and the outputs will slam to the positive rail. If the negative common-mode feedback path goes through the tail source, then the negative feedback gain decreases as the tail source is crushed, exacerbating the problem.

Some prior art solutions use a scaled down replica of the input differential pair to detect the crushing of the tail source. The problem with these prior art solutions is that the scaled down replica connects to the opamp's differential input. This adversely effects the matching of the input parasitics.

### SUMMARY OF THE INVENTION

An opamp has a common mode current injection circuit that monitors the amount of tail current “requested” by the primary common-mode feedback circuit. If this current exceeds the nominal tail current by a certain amount, additional common-mode current is injected into the first stage of the opamp, bypassing the tail 5 source and the input differential pair, to prevent the outputs from latching. This circuit is useful for an opamp in which the common mode feedback (CMFB) loop controls the tail current. When the “requested” tail current exceeds a threshold, additional current is pumped into the first stage to stabilize the CMFB loop.

### BRIEF DESCRIPTION OF THE DRAWINGS

In the drawings:

FIG. 1 is a schematic circuit diagram of a prior art 2-stage opamp with common mode feedback circuit;

FIG. 2 is a schematic circuit diagram of a preferred embodiment common mode current injection circuit.

### DESCRIPTION OF PREFERRED EMBODIMENTS

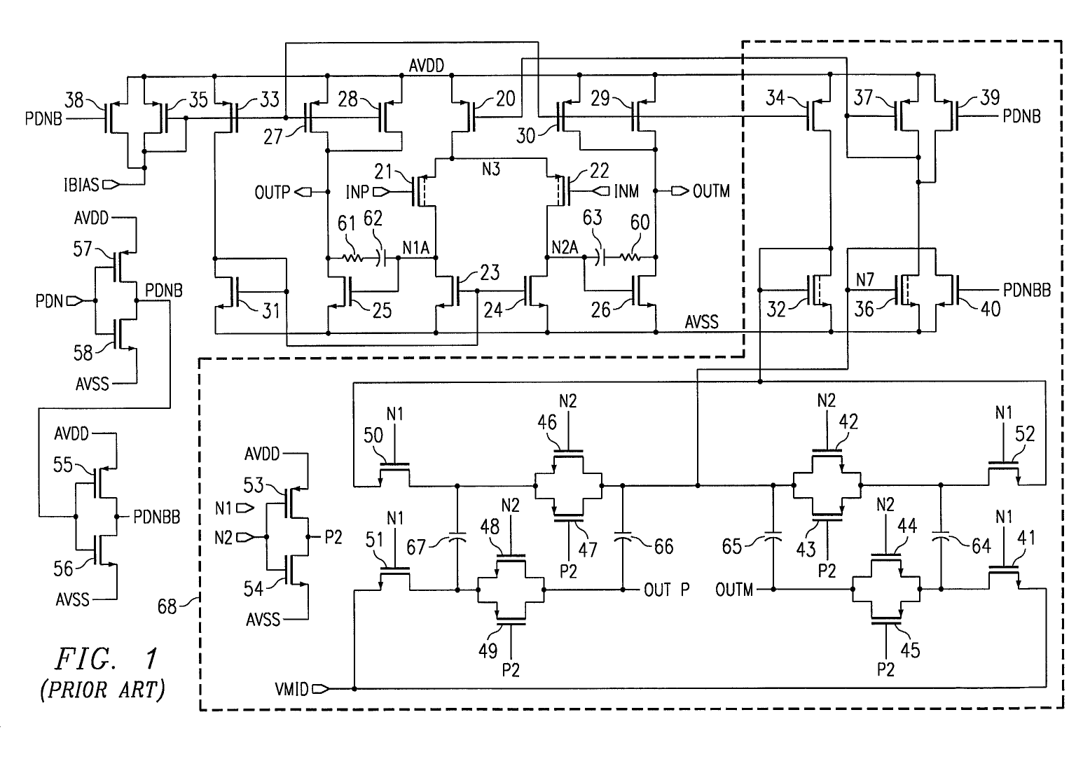

A prior art 2-stage opamp is shown FIG. 1. In this 2-stage opamp, the tail source is controlled by a common-mode feedback circuit. The circuit of FIG. 1 includes transistors 20-58; resistors 60 and 61; capacitors 62-67; current bias IBIAS; power down signals PDN, PDNB, and PDNBB; supply voltages AVDD and AVSS; differential inputs INP and INM; differential outputs OUTP and OUTM; common mode feedback controls N1, N2, and P2; and common mode feedback input VMID. Transistors 20-24 form the first stage (differential input stage). Transistors 25-30 form the second stage (differential output stage). The common mode feedback circuit 68 controls the current in transistor 20, which is the tail current source for the input differential pair formed by transistors 21 and 22.

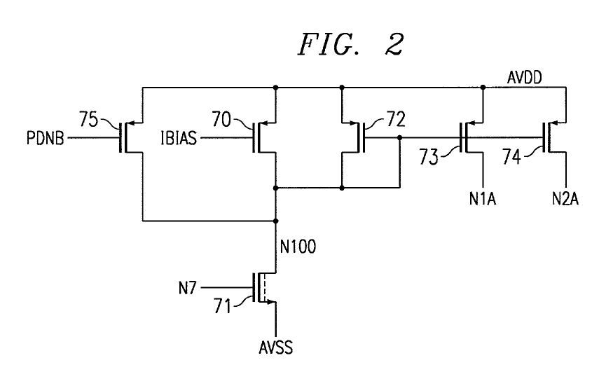

A preferred embodiment common mode current injection circuit is shown in FIG. 2. This circuit monitors the amount of tail current “requested” by the primary common-mode feedback circuit 68, shown in FIG. 1, and if this current exceeds the nominal tail current by a certain amount, additional common-mode current is injected into the first stage, bypassing the tail source and the input differential pair, to prevent the outputs from latching.

The preferred embodiment circuit of FIG. 2 includes transistors 70-75. The circuit of FIG. 2 is connected to the circuit of FIG. 1 at the common nodes N7, N1A, and N2A. The bias current node IBIAS is coupled to the gate of transistor 70. Transistor 75 is a power down switch. Current in transistor 36 (which is in the CMFB loop 62) is mirrored to transistor 71. Nominally,

I₇₁=1/2I₇₀

(I₇₀ is the nominal current for transistor 70 and I₇₁ is the nominal current for transistor 71), so node N100 is and transistors 73 and 74 are off. If current I₇₀ becomes greater than current I₇₁, which will happen if the tail source is crushed, node N100 will drop and transistors 73 and 74 will inject current into nodes N1A and N2A, preventing latchup.

The preferred embodiment circuit is useful for an opamp in which the common mode feedback (CMFB) loop controls the tail current. When the “requested” tail current exceeds a threshold, additional current is pumped into the first stage to stabilize the CMFB loop.

One advantage of the circuit of FIG. 2 is that it does not connect to the opamp's differential input, which makes it easier to add to the opamp without adversely effecting the matching of the input parasitics.

While this invention has been described with reference to an illustrative embodiment, this description is not intended to be construed in a limiting sense. Various modifications and combinations of the illustrative embodiment, as well as other embodiments of the invention, will be apparent to persons skilled in the art upon reference to the description. It is therefore intended that the appended claims encompass any such modifications or embodiments.

What is claimed is:

1. A circuit comprising:
a differential input pair;
a tail current source coupled to the differential input pair;
a common mode feedback circuit having an output coupled to a control node of the tail current source;
a current injection circuit for monitoring the output of the common mode feedback circuit and injecting current into nodes coupled to the differential input pair in response to the output of the common mode feedback circuit.

2. The circuit of claim 1 wherein the current injection circuit comprises:
a first transistor having a control node coupled to a bias node;
a second transistor coupled to the first transistor and having a control node coupled to the common mode feedback circuit;
a third transistor coupled to a first branch of the differential input pair and having a control node coupled to the first transistor; and
a fourth transistor coupled to a second branch of the differential input pair and having a control node coupled to the first transistor.

3. The circuit of claim 2 further comprising a fifth transistor coupled to the first transistor and having a control node coupled to the first transistor.

4. The circuit of claim 1 wherein the tail current source comprises a transistor coupled between a power supply node and the differential input pair.

5. The circuit of claim 1 wherein the differential input pair comprises first and second transistors coupled to the tail current source.

6. The circuit of claim 5 further comprising:
a third transistor coupled between the first transistor and a supply node; and
a fourth transistor coupled between the second transistor and a supply node, and having a control node coupled to the control node of the third transistor.

7. The circuit of claim 1 further comprising:
a first transistor coupled to a first differential output node and having a control node coupled to a first branch of the differential input pair; and
a second transistor coupled to a second differential output node and having a control node coupled to a second branch of the differential input pair.

8. The circuit of claim 7 further comprising:
a third transistor coupled to the first transistor and having a control node coupled to a bias node; and
a fourth transistor coupled to the second transistor and having a control node coupled to the bias node.

9. A 2-stage opamp circuit comprising:
a differential input stage;
a differential output stage coupled to the differential input stage;
a tail current source for supplying current to the differential input stage;
a common mode feedback circuit having inputs coupled to the differential output stage and having an output that controls the tail current source; and
a current injection circuit having an input coupled to the common mode feedback circuit and having outputs coupled to the differential input stage for supplying current to the differential input stage in response to the output of the common mode feedback circuit.

10. The circuit of claim 9 wherein the current injection circuit comprises:
a first transistor having a control node coupled to a bias node;
a second transistor coupled to the first transistor and having a control node coupled to the common mode feedback circuit;
a third transistor coupled to a first branch of the differential input stage and having a control node coupled to the first transistor; and
a fourth transistor coupled to a second branch of the differential input stage and having a control node coupled to the first transistor.

11. The circuit of claim 10 further comprising a fifth transistor coupled to the first transistor and having a control node coupled to the first transistor.

12. The circuit of claim 9 wherein the tail current source comprises a transistor coupled between a power supply node and the differential input stage.

13. The circuit of claim 9 wherein the differential input stage comprises first and second transistors coupled to the tail current source.

14. The circuit of claim 13 further comprising:
a third transistor coupled between the first transistor and a supply node; and
a fourth transistor coupled between the second transistor and the supply node, and having a control node coupled to the control node of the third transistor.

15. The circuit of claim 9 wherein the differential output stage comprises:
a first transistor coupled to a first differential output node and having a control node coupled to a first branch of the differential input stage; and
a second transistor coupled to a second differential output node and having a control node coupled to a second branch of the differential input stage.

16. The circuit of claim 15 further comprising:
a third transistor coupled to the first transistor and having a control node coupled to a bias node; and
a fourth transistor coupled to the second transistor and having a control node coupled to the bias node.

17. A method comprising:
monitoring a common mode feedback signal;
comparing a common mode feedback signal to a reference current;
providing current to the first stage in response to the common mode feedback signal.

18. An amplifier circuit comprising:
an input stage having a tail current source;
a common-mode feedback circuit for controlling the tail current source;
a current injection circuit for monitoring an output of the common mode feedback circuit and injecting current into the input stage when the output of the common mode feedback circuit exceeds a threshold.
